(19) United States
(12) Patent Application Publication
(10) Pub. No.: US 2009/0090653 A1
(43) Pub. Date: Apr. 9, 2009

(54) Low cost wafer box improvements

(76) Inventor: Valoris L Forsyth, Lewisville, TX (US)

Correspondence Address: Day Pitney, 7 Times Square, New York, NY, 10036-7311, US

(21) Appl. No.: 11/920,028

(22) PCT Filed: May 18, 2004
(86) PCT No.: PCT/US2004/015480

§ 371 Date: Nov. 5, 2008

Related U.S. Application Data
(60) Provisional application No. 60/515,869, filed on Oct. 29, 2003.

(51) Int. Cl. H01L 21/673; B65D 21/02; B65D 81/02; B65D 85/30

(52) U.S. Cl. 206/710; 206/776; 206/504; 206/521

(57) ABSTRACT

The wafer box includes a tray (10) and a cover (62). The tray (10) includes an inner (34, 36, 38, 40) and outer (24, 26, 28, 30) wall configuration with horizontal semicircular channels (48, 50, 52, 54) therebetween to perform spacing, strengthening and horizontal shock-absorbing functions. The tray (10) further includes a wafer cavity (42) formed within the inner wall (34, 36, 38, 40). The wafer cavity (42) includes a lattice (46) of ridges on the floor thereof to provide a vertical shock absorbing function. The wall (76, 78, 80, 82) of the cover (62) engages and mates to the outer wall (24, 26, 28, 30) of the tray (10) thereby forming a double wall configuration. A pedestal configuration (90, 92) is formed on the corners and mid-spans of the top of the cover (62) to provide standoff clearance between the inter-stacked boxes to minimize or eliminate the transmission of shock and vibration through an inter-stack configuration.

This application claims priority from provisional application Ser. No. 60/515,869, filed Oct. 29, 2003.

### BACKGROUND OF THE INVENTION

1. Field of the Invention

The present invention relates to a containment device or wafer box for transporting semiconductor wafers, particularly utilizing thermoformed material in place of other transport wafer packaging systems utilized in shipping wafers from a front-end wafer fabrication facility to a back-end product manufacturing facility.

2. Description of the Prior Art

The prior art contains a variety of designs for the containment and transport of semiconductor wafers. These designs must provide both electrostatic and mechanical protection for the wafers contained therein. Preferably, such containment devices should be easily adaptable to various automated apparatus which load or unload the semiconductor wafers. Such containment devices should have a simple design which is reliable and economical to mass produce. Additionally, such containment devices should be compliant to industry standards to achieve equipment handling capability.

Examples of some prior art are U.S. Pat. No. 6,193,068 entitled “Containment Device for Retaining Semiconductor Wafers” issued on Feb. 27, 2001 to Lewis et al.; U.S. Pat. No. 6,286,684 entitled “Protective System for Integrated Circuit (IC) Wafers Retained Within Containers Designed for Storage and Shipment” issued on Sep. 11, 2001 to Brooks et al.; U.S. Pat. No. 6,003,674 entitled “Method and Apparatus for Packing Contaminant-Sensitive Articles and Resulting Package” issued on Dec. 21, 1999 to Brooks; and U.S. Pat. No. 5,724,748 entitled “Apparatus for Packaging Contaminant-Sensitive Articles and Resulting Package” issued on Mar. 10, 1998 to Brooks et al.

### OBJECTS AND SUMMARY OF THE INVENTION

In order to attain the above and other objects, the wafer box of the present invention includes a bottom floor attachment design which mechanically isolates wafers from side walls thereby acting as a shock absorber against vertical impact and vibration; a side wall configuration which isolates interior walls and the cavity from horizontal shock impact; a pedestal configuration at the corners and mid-span which provides standoff clearance when full boxes are inter-stacked so that shock and vibration are not transmitted through the inter-stack configuration; a side wall configuration comprised of mating surfaces from the lid and bottom to create a double thickness wall thereby allowing substantially increased stacking capabilities; interlocking engagement elements on four sides to provide full engagement and survival of multiple drops of fully loaded wafer boxes (typically including 16 semiconductor wafers); interlocked offset flanges to provide for simple separation of the base from the lid; a large side wall flat surface to provide for the attachment of a large label along the side of the wafer box; and translucent material along the top of the wafer box so that large print paperwork is visible through the top of the box in order to reduce or eliminate the need for additional labels around the box.

Optionally, the wafer box can include a side wall collapsible configuration through engagement of the lid to the base interface. This could be accomplished either by the vertical insertion of the lid over the base or through a living hinge folding action of the lid around the base. This provides for the reduction of excess movement of the semiconductor wafers in the cavity of the wafer box.

### BRIEF DESCRIPTION OF THE DRAWINGS

Further objects and advantages will become apparent from the following description and from the accompanying drawings, wherein:

FIG. 1 is a top plan view of the tray of the wafer box of the present invention.

FIG. 2 is a side plan view of the tray of the wafer box of the present invention.

FIG. 3 is a front plan view of the tray of the wafer box of the present invention.

FIG. 4 is a perspective view of the tray of the wafer box of the present invention.

FIG. 5 is a top plan view of the cover of the wafer box of the present invention.

FIG. 6 is a side plan view of the cover of the wafer box of the present invention.

FIG. 7 is a front plan view of the cover of the wafer box of the present invention.

FIG. 8 is a perspective view of the cover of the wafer box of the present invention.

### DETAILED DESCRIPTION OF THE PREFERRED EMBODIMENT

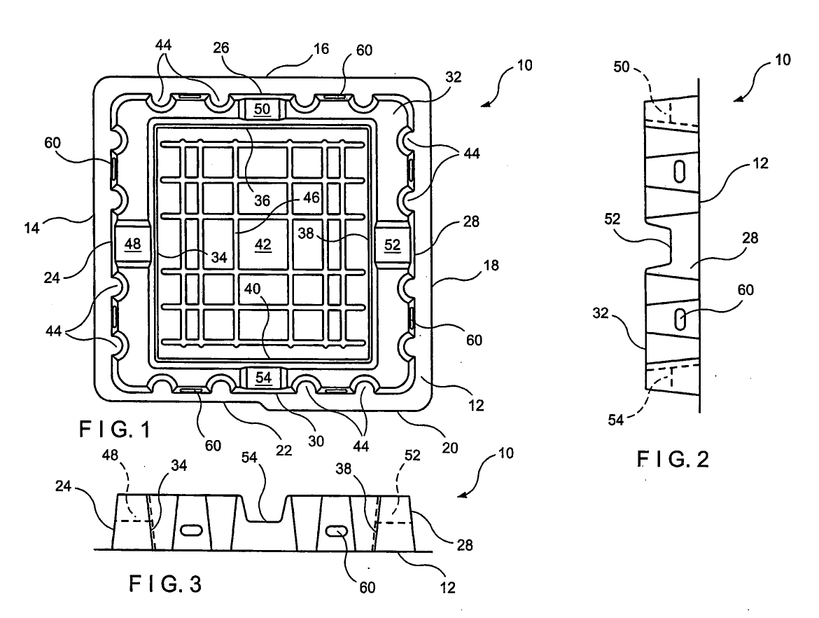

Referring now to the drawings in detail wherein like numerals indicate like elements throughout the several views, one sees from FIGS. 1-4 that the tray 10 of the wafer box of the present invention includes a planar base 12 which is square or rectangular in shape, as bounded by sides 14, 16, 18, 20. Side 20 includes an indented area 22. Indented area 22, in combination with a similar indented area on the cover as will be described hereinafter in more detail, provides the opportunity for the user, or even automated machinery, to separate easily the tray 10 from the cover. Outer walls 24, 26, 28, 30 rise inwardly adjacent from sides 14, 16, 18, 20, respectively, and terminate in elevated planar ledge area 32. Inner walls 34, 36, 38, 40 extend from the interior of elevated planar ledge area 32 to planar base 12 thereby forming wafer cavity 42 therewithin.

Outer walls 24, 26, 28, 30 include semi-circular downwardly tapered concave portions 44 which add to the rigidity of the outer walls. Furthermore, the portion of planar base 12 within wafer cavity 42 includes lattice 46 of ridges thereby mechanically isolating any wafers (not shown) within wafer cavity 42 from inner walls 34, 36, 38, 40 and acting as a shock absorber against vertical impact and vibration.

Similarly, horizontal semi-circular channels 48, 50, 52, 54 are formed between respective outer walls 24, 26, 28, 30 and inner walls 34, 36, 38, 40. Channels 48, 50, 52, 54 perform spacing, strengthening and horizontal shock-absorbing functions.

A pair of detent dimples 60 is formed on each of outer walls 24, 26, 28, 30 at about the one quarter and three quarters position along the span of each of the outer walls.

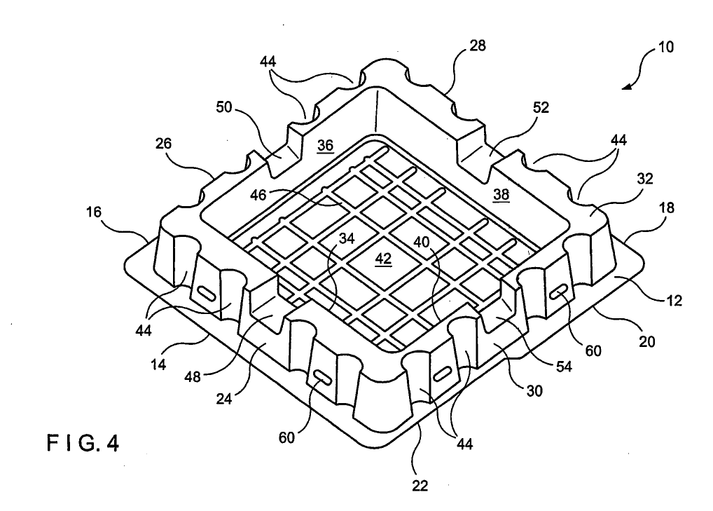

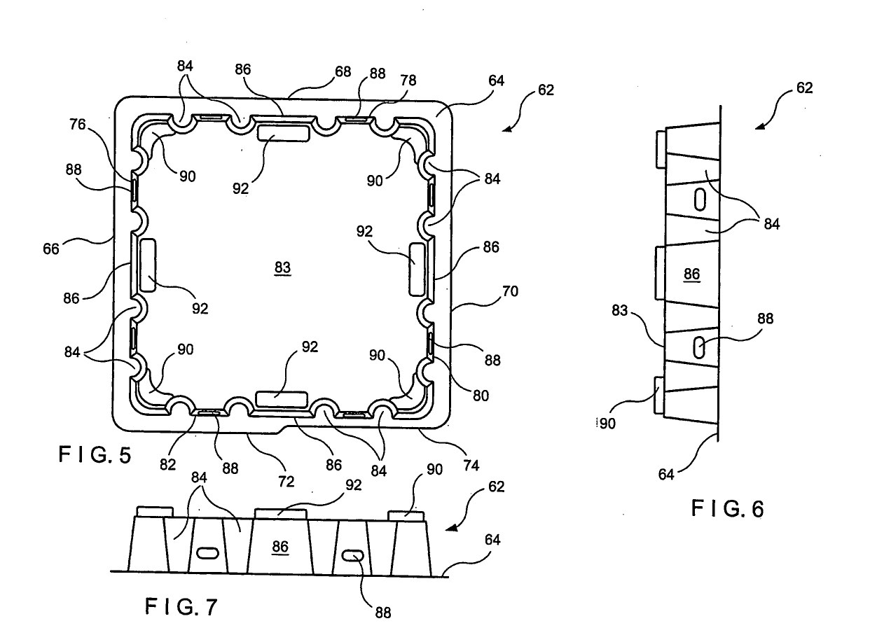

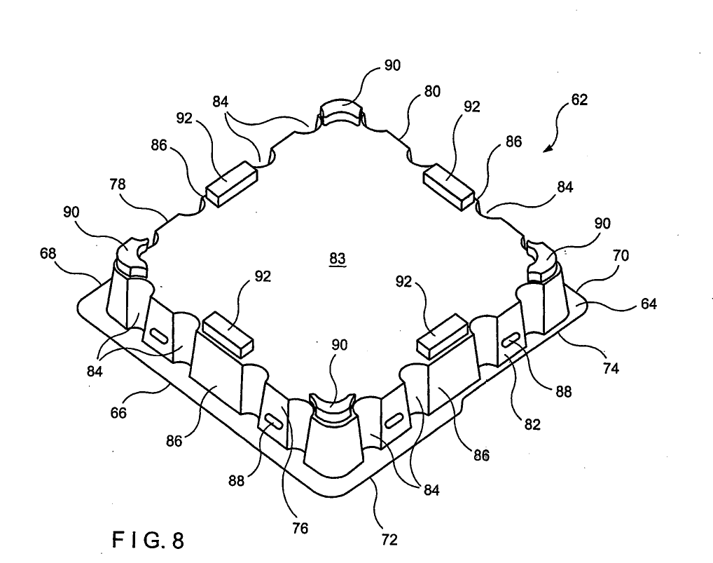

One sees from FIGS. 5-8 that cover 62 of the wafer box includes lower rim 64 bounded by sides 66, 68, 70, 72 which generally correspond to the footprint of base 12 of tray 10. However, side 72 includes indented area 74 which is intended to be laterally offset from indented area 22 when side 72 of cover 62 is aligned with side 20 of tray 10. That is, when viewed from the perspective of FIGS. 4 and 8, indented area 22 is on the left portion of side 20 while indented area 74 is on the right portion of side 72. This forms an interlocked offset flange configuration which allows the user to grasp sides 20 and 72 between a thumb and forefinger and disengage cover 62 from tray 10 with a simple twisting motion.

Cover side walls 76, 78, 80, 82 rise from lower rim 64 and terminate in cover upper planar surface 83. Cover upper planar surface 83 may be formed of translucent material so that (large print) printed material inside may reduce the need for labeling of the wafer box. Cover side walls 76, 78, 80, 82 are shaped so as to be able to outwardly engage outer walls 24, 26, 28, 30 when cover 62 is placed over tray 10 thereby forming a double thickness outer wall configuration. Cover side walls 76, 78, 80, 82 include semi-circular downwardly tapered concave portions 84 which outwardly engage and mate to semi-circular downwardly tapered concave portions 44 of tray 10 in the installed position. Central planar label areas 86 are formed at a central portion of each of cover side walls 76, 78, 80, 82, between the two interior semicircular concave portions 84.

A pair of detent dimples 88 is formed on each of cover side walls 76, 78, 80, 82 at about the one quarter and three quarters position along the span of each of the cover side walls. When cover 62 is installed over tray 10, detent dimples 88 of cover 62 extend into detent dimples 60 of tray 10 thereby forming a detent relationship.

Corner pedestals 90 rise from the intersections of the cover side walls 76, 78, 80, 82 while mid-span pedestals 92 rise from the mid-point of cover side walls 76, 78, 80, 82. Pedestals 90, 92 provide standoff clearance when full wafer boxes are inter-stacked so that transmission of shock and vibration through the inter-stack configuration is minimized or eliminated.

Tray 10 and cover 62 are typically formed of thermoformed material, although those skilled in the art will recognize a range of equivalents after review of this disclosure.

To use the resulting wafer box, semiconductor wafers (not shown) are loaded into wafer cavity 42 of tray 10. Cover 62 is then placed vertically over tray 10 so that detent dimples 88 of cover 62 extend into detent dimples 60 of tray 10 thereby forming a detent relationship, semi-circular downwardly tapered concave portions 84 of cover 62 outwardly engage and mate to semi-circular downwardly tapered concave portions 44 of tray 10, and indented areas 22 and 74 are laterally offset from each other thereby forming an interlocked offset flange configuration.

Thus the several aforementioned objects and advantages are most effectively attained. Although a single preferred embodiment of the invention has been disclosed and described in detail herein, it should be understood that this invention is in no sense limited thereby and its scope is to be determined by that of the appended claims.

What is claimed is:

1. A container for semiconductor wafers, comprising:
a tray element including a planar base, outer side walls rising from said planar base, inner side walls formed inwardly adjacent from said outer side walls and forming a wafer containment area therewithin, and lateral shocking absorbing means formed between said inner side walls and said outer side walls; and
a cover element including a planar top and cover side walls extending from said planar top wherein, when said cover element is engaged with said tray element, said cover side walls are outwardly adjacent from said outer walls of said tray element.

2. The container for semiconductor wafers of claim 1 wherein said outer side walls include first semi-circular concave portions and said cover side walls include second semicircular concave portions wherein, when said cover element is engaged with said tray element, said first semi-circular concave portions engage said second semi-circular concave portions.

3. The container for semiconductor wafers of claim 2 wherein said first and second semi-circular concave portions are downwardly tapered.

4. The container for semiconductor wafers of claim 1 wherein said lateral shock absorbing means comprises channels formed between respective said inner side walls and said outer side walls.

5. The container for semiconductor wafers of claim 4 wherein said channels are formed by walls perpendicular to said inner side walls and said outer side walls.

6. The container for semiconductor wafers of claim 5 wherein said channels are semi-circular.

7. The container for semiconductor wafers of claim 1 wherein said planar base includes protrusions which form lower shock absorbing means.

8. The container for semiconductor wafers of claim 7 wherein said protrusions form a lattice of ridges.

9. The container for semiconductor wafers of claim 1 wherein said cover side walls terminate in a rim, said rim including a portion which is parallel to said planar top.

10. The container for semiconductor wafers of claim 9 wherein, when said cover element is engaged with said tray element, said rim abuts with a portion of said planar base outward from said outer side walls.

11. The container for semiconductor wafers of claim 10 wherein said rim includes first indented areas and wherein said planar base outward from said outer side walls includes second indented areas.

12. The container for semiconductor wafers of claim 11 wherein said first indented areas are offset from said second indented areas thereby forming an interlocked offset flange configuration facilitating the separation of said cover element from said tray element.

13. The container for semiconductor wafers of claim 1 wherein said outer side walls include first detent elements and said cover side walls include second detent elements wherein, when said cover element is engaged with said tray element, said first detent elements engage said second detent elements.

14. The container for semiconductor wafers of claim 13 wherein said first detent elements and said second detent elements are dimples.

15. The container for semiconductor wafers of claim 1 wherein said planar top includes offset elements to offset the container from a successive upper container.

16. The container for semiconductor wafers of claim 15 wherein said offset elements include pedestal elements formed on said planar top at intersections of said cover side walls.

17. The container for semiconductor wafers of claim 15 wherein said offset elements include pedestal elements formed on said planar top at mid-spans of said cover side walls.

18. The container for semiconductor wafers of claim 1 wherein at least a portion of said planar top is translucent.

19. The container for semiconductor wafers of claim 1 wherein said cover side walls include central planar label areas.

20. The container for semiconductor wafers of claim 1 wherein said tray element and said cover element are formed of thermoformed plastic.
